(19) United States
(12) Patent Application Publication
(10) Pub. No.: US 2025/0194300 A1
(43) Pub. Date: Jun. 12, 2025

(54) LIGHT EMITTING DEVICES AND METHODS OF MANUFACTURE

(71) Applicant: THE REGENTS OF THE UNIVERSITY OF MICHIGAN, Ann Arbor, MI (US)

(72) Inventors: Ayush PANDEY, Ann Arbor, MI (US); Jungwook MIN, Ann Arbor, MI (US); Yakshita MALHOTRA, Ann Arbor, MI (US); Maddaka REDDEPPA, Ann Arbor, MI (US); Yixin XIAO, Ann Arbor, MI (US); Zetian MI, Ann Arbor, MI (US); Jiangnan LIU, Ann Arbor, MI (US); Yuanpeng WU, Ann Arbor, MI (US)

(21) Appl. No.: 19/050,767

(22) Filed: Feb. 11, 2025

Related U.S. Application Data
(63) Continuation of application No. PCT/US2023/030176, filed on Aug. 14, 2023.
(60) Provisional application No. 63/397,769, filed on Aug. 12, 2022.
(60) Provisional application No. 63/412,295, filed on Sep. 30, 2022.

(51) Int. Cl. H10H 20/815; H10H 20/01; H10H 20/812; H10H 20/813; H10H 20/821; H10H 20/825; H10H 20/831

(52) U.S. Cl. CPC H10H 20/815; H10H 20/01335; H10H 20/812; H10H 20/8132; H10H 20/821; H10H 20/8252; H10H 20/8316

(57) ABSTRACT

Light emitting nanowire devices, in accordance with aspects of the present technology, can include a short period superlattice (SPSL) region underlaying an N-polar multiple quantum well (MQW) region. The short period superlattice (SPSL) region can relax strain in the multiple quantum well (MQW) region. The nanowires can be submicron scale and characterized by red electroluminescence.

### CROSS-REFERENCE TO RELATED APPLICATIONS

This application is a continuation application of Patent Cooperation Treaty (PCT) Application No. PCT/US2023/030176 filed Aug. 14, 2023, which claims priority to U.S. Provisional Patent Application No. 63/397,769 filed Aug. 12, 2022 and U.S. Provisional Patent Application No. 63/412,295 filed Sep. 30, 2022, which are incorporated herein in their entirety.

### BACKGROUND OF THE INVENTION

Significant efforts have been put into the development of efficient micro light emitting devices (μLED) for future display technologies, due to their marked benefits over existing displays. However, traditionally the efficiency of micro light emitting devices (μLED) remain one or two orders of magnitude lower than conventional broad-area light emitting devices, particularly for red light emitting devices. The deterioration in device performance with smaller device sizes has been linked to plasma damage induced in the mesa sidewalls of conventional device fabrication techniques for light emitting devices. Therefore, there is a continuing need for improved light emitting devices and methods of manufacturing.

### SUMMARY OF THE INVENTION

The present technology may best be understood by referring to the following description and accompanying drawings that are used to illustrate embodiments of the present technology directed toward light emitting devices and methods of manufacturing. Aspects of the present technology advantageously provide efficient and effective strain engineered light emitting device. Strain engineered N-polar type III-V nanowires in accordance with aspects of the present technology can realize highly efficient red light emitting devices at a micrometer scale.

In one embodiment, a light emitting device can include a short period superlattice (SPSL) region, and a multiple quantum well (MQW) region disposed on the short period superlattice (SPSL) region. The light emitting device can emit red light with a peak external quantum efficiency (EQE) of 2% or greater, and a wall-plug efficiency (WPE) of 1.5% or greater.

In another embodiment, a micro light emitting device can include one or more nanowires. Each nanowire can include: a semiconductor region having a first doping type; a short period superlattice (SPSL) region disposed on the semiconductor region having the first doping type; a N-polar multiple quantum well (MQW) region disposed on the short period superlattice (SPSL) region opposite the semiconductor region having the first doping type; and a tunnel junction region having a second doping type disposed on the N-polar multiple quantum well (MQW) region opposite the short period superlattice (SPSL) region.

The short period superlattice (SPSL) region can reduces/relaxes lattice strain in the N-polar multiple quantum well (MQW) region. The short period superlattice (SPSL) region increases indium incorporations in the N-polar multiple quantum well (MQW) region.

In yet another embodiment, a method of manufacturing a micro light emitting device (μLED) can include: epitaxially depositing a doped semiconductor region; epitaxially depositing a short period superlattice (SPSL) region on the doped semiconductor region; epitaxially depositing a N-polar multiple quantum well (MQW) region on the short period superlattice (SPSL) region opposite the doped semiconductor region; and epitaxially depositing a doped tunnel junction region on the N-polar multiple quantum well (MQW) region opposite the short period superlattice (SPSL) region. The method can further include relaxing a lattice structure of the short period superlattice (SPSL) region; and relaxing a lattice structure of the N-polar multiple quantum well (MQW) region. The short period superlattice (SPSL) region can further relax the lattice structure of the N-polar multiple quantum well (MQW) region. The N-polar multiple quantum well (MQW) region can comprise N-polar indium gallium nitride (InGaN) quantum wells (QW), wherein the short period superlattice (SPSL) region can act to increase indium (In) incorporation in the—polar indium gallium nitride (InGaN) quantum wells (QW). The doped tunnel junction region can include magnesium (Mg) doped gallium nitride (GaN) region, with a magnesium (Mg) concentration of greater than 1020 atoms/cm⁻³.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

Embodiments of the present technology are illustrated by way of example and not by way of limitation, in the figures of the accompanying drawings and in which like reference numerals refer to similar elements and in which:

FIG. 1 shows a nanowire, in accordance with aspects of the present technology.

FIG. 2 shows a method of manufacturing the nanowire, in accordance with aspects of the present technology.

FIG. 3 shows a micro light emitting device (μLED), in accordance with aspects of the present technology.

FIG. 4 shows a method of manufacturing a micro light emitting device (μLED), in accordance with aspects of the present technology.

FIGS. 5A-5C show semiconductor crystalline structures.

FIG. 6A shows an exemplary scanning electron microscope (SEM) image of nanowires, in accordance with aspects of the present technology.

FIG. 6B shows a graph of exemplary stacked photoluminescence (PL) spectra of the nanowire samples, in accordance with aspects of the present technology.

FIG. 7A shows exemplary simulated J-V characteristics of a nanowire, in accordance with aspects of the present technology.

FIG. 7B shows band diagrams at equilibrium of a nanowire, in accordance with aspects of the present technology.

FIG. 7C shows relative ratio of radiative recombination of a nanowire, in accordance with aspects of the present technology.

FIG. 8A shows a graph of exemplary J-V characteristics of a nanowire, in accordance with aspects of the present technology.

FIG. 8B shows a graph of exemplary L-I characteristics of a nanowire, in accordance with aspects of the present technology.

FIG. 8C shows corresponding external quantum efficiency (EQE) and wall-plug efficiency (WPE) plots for a nanowire, in accordance with aspects of the present technology.

FIG. 9A shows a graph plot of an exemplary electroluminescence spectra for a nanowire at different injection currents, in accordance with aspects of the present technology.

FIG. 9B shows a graph plot of an exemplary electroluminescence spectra for a nanowire at different injection currents, in accordance with aspects of the present technology.

FIG. 10 shows a method of manufacturing a micro light emitting device (μLED), in accordance with aspects of the present technology.

FIG. 11A shows a scanning electron microscope (SEM) image of a micro light emitting device (μLED), in accordance with aspects of the present technology.

FIG. 11B shows a photoluminescence (PL) spectrum of micro light emitting device (μLED), in accordance with aspects of the present technology.

FIG. 12A shows a graph of an exemplary J-V characteristics of a micro light emitting device (μLED), in accordance with aspects of the present technology.

FIG. 12B shows a graph of an exemplary L-I characteristics of a micro light emitting device (μLED), in accordance with aspects of the present technology.

FIG. 13A shows exemplary EQE for the micro light emitting device (μLED) at different injection currents, in accordance with aspects of the present technology.

FIG. 13B shows exemplary WPE for the micro light emitting device (μLED) at different injection currents, in accordance with aspects of the present technology.

FIG. 14 shows an exemplary normalized electroluminescence (EL) spectra for the micro light emitting device (μLED), in accordance with aspects of the present technology.

FIG. 15 shows variation of peak EQE with active region area of micro light emitting device (μLED), in accordance with aspects of the present technology.

### DETAILED DESCRIPTION OF THE INVENTION

Reference will now be made in detail to the embodiments of the present technology, examples of which are illustrated in the accompanying drawings. While the present technology will be described in conjunction with these embodiments, it will be understood that they are not intended to limit the technology to these embodiments. On the contrary, the invention is intended to cover alternatives, modifications and equivalents, which may be included within the scope of the invention as defined by the appended claims. Furthermore, in the following detailed description of the present technology, numerous specific details are set forth in order to provide a thorough understanding of the present technology. However, it is understood that the present technology may be practiced without these specific details. In other instances, well-known methods, procedures, components, and circuits have not been described in detail as not to unnecessarily obscure aspects of the present technology.

Some embodiments of the present technology which follow are presented in terms of routines, modules, logic blocks, and other symbolic representations of operations on data within one or more electronic devices. The descriptions and representations are the means used by those skilled in the art to most effectively convey the substance of their work to others skilled in the art. A routine, module, logic block and/or the like, is herein, and generally, conceived to be a self-consistent sequence of processes or instructions leading to a desired result. The processes are those including physical manipulations of physical quantities. Usually, though not necessarily, these physical manipulations take the form of electric or magnetic signals capable of being stored, transferred, compared and otherwise manipulated in an electronic device. For reasons of convenience, and with reference to common usage, these signals are referred to as data, bits, values, elements, symbols, characters, terms, numbers, strings, and/or the like with reference to embodiments of the present technology.

It should be borne in mind, however, that these terms are to be interpreted as referencing physical manipulations and quantities and are merely convenient labels and are to be interpreted further in view of terms commonly used in the art. Unless specifically stated otherwise as apparent from the following discussion, it is understood that through discussions of the present technology, discussions utilizing the terms such as “receiving,” and/or the like, refer to the actions and processes of an electronic device such as an electronic computing device that manipulates and transforms data. The data is represented as physical (e.g., electronic) quantities within the electronic device's logic circuits, registers, memories and/or the like, and is transformed into other data similarly represented as physical quantities within the electronic device.

In this application, the use of the disjunctive is intended to include the conjunctive. The use of definite or indefinite articles is not intended to indicate cardinality. In particular, a reference to “the” object or “a” object is intended to denote also one of a possible plurality of such objects. The use of the terms “comprises,” “comprising,” “includes,” “including” and the like specify the presence of stated elements, but do not preclude the presence or addition of one or more other elements and or groups thereof. It is also to be understood that although the terms first, second, etc. may be used herein to describe various elements, such elements should not be limited by these terms. These terms are used herein to distinguish one element from another. For example, a first element could be termed a second element, and similarly a second element could be termed a first element, without departing from the scope of embodiments. It is also to be understood that when an element is referred to as being “coupled” to another element, it may be directly or indirectly connected to the other element, or an intervening element may be present. In contrast, when an element is referred to as being “directly connected” to another element, there are not intervening elements present. It is also to be understood that the term “and or” includes any and all combinations of one or more of the associated elements. It is also to be understood that the phraseology and terminology used herein is for the purpose of description and should not be regarded as limiting.

Microscale light emitting devices (μLED) are considered a next step in the evolution of light emitting device (LED) technology, and are projected to show tremendous growth in the near future as they are incorporated in many emerging technologies, such as but not limited to virtual/augmented reality, ultrahigh resolution mobile displays, wearable electronics, biomedical sensing, and ultrahigh speed optical interconnect. Type III-nitride semiconductors have been established as the dominant material system for visible light emitting device applications, and they are poised to be used as the basis for micro light emitting devices (μLED) as well. The lower surface recombination velocity of the type III-nitrides make them less susceptible, compared to other materials such as aluminum gallium indium phosphate (AlGalnP), to non-radiative surface recombination. To date, however, the efficiency of micro light emitting devices do not typically achieve external quantum efficiencies of greater than 1% for a lateral dimension of 1 micrometer (μm) or less. The efficiency bottleneck of micro light emitting devices has been fundamentally limited by structural damage and defects induced by etching during the fabrication of conventional quantum well structures. Furthermore, while InGaN-based light emitting devices have been shown with exceptional efficiencies in the blue wavelength range, their efficiency drops at longer wavelengths. For attaining longer emission wavelengths using an InGaN alloy, a higher amount of indium (In) (e.g., 30-40%) is typically required, which is not trivial. Phase separation is commonly seen in InGaN due to the low miscibility of the allow. Large lattice mismatch between the InGaN active region and the underlying GaN layer can induce the formation of extensive defects, while also subjecting the InGaN layer to a high compressive strain. The piezoelectric field induced by the strain is a major cause for the quantum-confined Stark effect (QCSE) which reduces radiative recombination efficiency by spatially separating the electron and hole wavefunction within typical quantum well active regions.

In aspects of the present technology, novel nanoscale engineering approaches are utilized to effectively relax strain in red emitting light emitting device heterostructures, including the use of porous gallium nitride (GaN) templates, V-pits, and nanostructures. In one exemplary implementation, red light emitting devices are realized by growing a 100% biaxially relaxed InGaN/GaN superlattice buffer. The layer can be relaxed through the annealing and thermal decomposition of an InGaN underlayer. In one embodiment, tunnel junctions are also incorporated to improve the carrier injection in red light emitting devices, showing an external quantum efficiency (EQE) of 4.5% for a device size of 60 μm×60 μm. In one embodiment, nanowires are employed to grow substantially dislocation free nanostructures that cover the entire visible spectrum, due to the efficient strain relaxation. Moreover, by epitaxially growing nanostructure device, the plasma etch process used in conventional quantum well light emitting device fabrication can be removed, thereby avoiding damage to the sidewalls of the active region. The sidewalls can be further passivated using atomic layer deposition (ALD), which can also fill gaps between nanowires, eliminating a possible route of the formation of leakage paths. In one embodiment, the critical advantages of N-polar GaN nanowires in achieving high efficiency sub-micron scale light emitting devices are leveraged, including improved hole injection into the active region and increased indium (In) incorporation as compared to nanostructures grown in the conventional Ga-polar orientation.

In accordance with aspects of the present technology, efficient micron-scale red emitting nanowire light emitting devices are realized. The N-polar InGaN/GaN nanowire light emitting devices can be grown utilizing plasma-assisted molecular beam epitaxy (MBE) with controlled diameters, spacing surface morphology, and polarity. To achieve strong red emission (e.g., >620 nm) from InGaN/GaN nanowires, and InGaN/GaN short period superlattice (SPLS) region is incorporated underneath and N-polar InGaN/GaN multiple quantum well (MQW) region to relax strain and enable the growth of red emitting InGaN active region at relatively higher temperatures, thereby reducing the density of point defects and impurities, which otherwise generally limit the optical characteristics of In-rich N-polar InGaN. In one embodiment, a peak external quantum efficiency (EQE) and wall-plug efficiency (WPE) of 2.2% and 1.7% were measured, respectively, for a light emitting device with a lateral dimension of approximately 0.8 μm, which is more efficient than typical conventional submicron scale red light emitting devices. In one exemplary implementation, detailed analysis of the charge carrier transport, injection, and recombination is performed in such strain-engineered red emitting light emitting devices, which offer a new path to overcome the efficiency bottleneck of red emitting micro light emitting devices for a broad range of applications.

Light emitting nanowire devices, in accordance with aspects of the present technology, can include a short period superlattice (SPSL) region underlaying an N-polar multiple quantum well (MQW) region. The short period superlattice (SPSL) region can relax strain in the multiple quantum well (MQW) region. The nanowires can be submicron scale and characterized by red electroluminescence.

In accordance with aspects of the present technology, a doped semiconductor region is grown utilizing selective area epitaxy techniques on a substrate. A short period superlattice (SPSL) region can be grown on the doped semiconductor region utilizing selective area epitaxy. A N-polar multiple quantum well (MQW) region can be grown on the short period superlattice (SPSL) region utilizing selective area epitaxy. A tunnel junction region can be grown on the N-polar multiple quantum well (MQW) region utilizing selective area epitaxy.

The doped semiconductor region can be a group III-V semiconductor compound doped with a first type of dopant grown with an N-polar crystalline lattice structure utilizing selective area epitaxy deposition. The short period superlattice (SPSL) region can be a plurality of group III-V monolayers interleaved with group III-V-nitride monolayers grown with a N-polar crystalline lattice structure utilizing selective area epitaxy deposition. The N-polar multiple quantum well (MQW) region can be a plurality of quantum well layers interleaved with barrier layers grown with a N-polar crystalline lattice structure utilizing selective area epitaxy deposition. The N-polar tunnel junction region can be a group III-V semiconductor compound doped with a second type of dopant grown with an N-polar crystalline lattice structure utilizing selective area epitaxy deposition.

In accordance with embodiments of the present technology, the nanowires can include an N-polar type III-nitride multiple quantum well region that is substantially dislocation free, with an underlying type III-nitride short period super lattice (SPSL) that can relax train and incorporate more type III element in the quantum well regions, to achieve strong red emission (e.g., >620 nm). In one implementation, submicron scale nanowire devices show red electroluminescence dominantly from indium gallium nitride (InGaN) multiple quantum well (MQW) active regions at low to moderate injection currents.

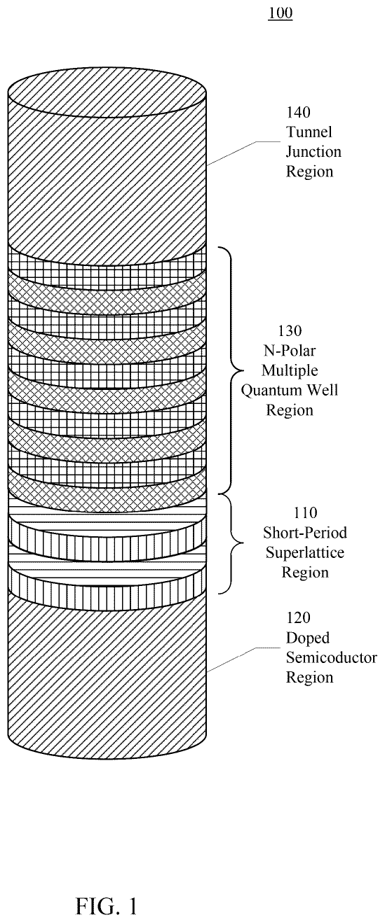

Referring to FIG. 1, a nanowire, in accordance with aspects of the present technology, is shown. The nanowire 100 can include a short period superlattice (SPSL) region 110 disposed on a doped semiconductor region 120. The nanowire 100 further includes an N-polar multiple quantum well (MQW) region 130 disposed on the short period superlattice (SPSL) region 110. The nanowire 100 can further include a tunnel junction region 140 disposed on the N-polar multiple quantum well (MQW) region 130.

In one embodiment, the doped semiconductor region 120 can comprise a group III-V compound semiconductor with a first type of doping and a N-polar (e.g., 0001) lattice geometry (e.g., nitride terminated lattice geometry). In one implementation, the doped semiconductor region 120 can be a silicon (Si) doped (e.g., n-doped) gallium-nitride (GaN) region. In one embodiment, the short period superlattice (SPSL) region can be a short period (e.g., few atomic layers) structure of group III-V compound semiconductor atomic monolayers. In one implementation, the short period superlattice (SPSL) region can include m layers of indium gallium nitride (InGaN) and n layers gallium nitride (GaN) arranged in a short period of 3-7 interleaved layers. In one embodiment, the N-polar multiple quantum well (MQW) region 130 can be a group III-V compound semiconductor of alternating quantum wells (QW) and quantum barriers (WB). In one implementation, the N-polar multiple quantum well (MQW) region 130 can be a plurality of alternating indium gallium nitride (InGaN) quantum wells (QW) and gallium nitride (GaN) quantum barriers (QB). In one embodiment, the tunnel junction region 140 can comprise a group III-V compound semiconductor with a second type of doping. In one implementation, the tunnel junction region 140 can be a magnesium (Mg) doped (e.g., p-doped) gallium-nitride (GaN) region.

The nanowire 100 can have a substantially hexagonal, square, rectangular, rhombic, polygonal, circular or elliptical cross-sectional shape. In one implementation, the nanowire 100 can have a hexagonal or circular cross-section diameter.

In one implementation, the short period superlattice (SPSL) region 110 relaxes/reduces strain. The short period superlattice (SPSL) region 110 can also facilitate incorporation of more quantum configurations (e.g., quantum wells, quantum lines, quantum dots, nanoclusters, etc.). In one implementation, short period superlattice (SPSL) region 110 is configured to incorporate more indium (In) within the InGaN N-polar multiple quantum well (MQW) region 130. The short period superlattice (SPSL) region 110 can also help facilitate reduction of extensive defects and dislocations (e.g., for indium-rich InGaN quantum wells, etc.), strain induced quantum-confined Stark effect, and etch-induced surface damage during the fabrication of quantum well μLEDs.

In one embodiment, the m layers of the short period superlattice (SPSL) can have a high elastic constant and the n layer can have a low elastic constant (or vise versa, etc.). In one embodiment, the short period superlattice (SPSL) region can include a lower dimensional structure (e.g., an array of quantum dots, quantum wires, etc.). In one embodiment, the materials of the short period superlattice (SPSL) region can have different band gaps. In one exemplary implementation, the materials may be divided by the element groups IV, III-V and II-VI. In one embodiment, at least two of the plurality of quantum wells (QW) within the N-polar multiple quantum well (MQW) region are not uniform. In one embodiment, N-polar multiple quantum well (MQW) region is considered an intermediate region between a p-type region and a n-type region (e.g., a P-I-N configuration, etc.).

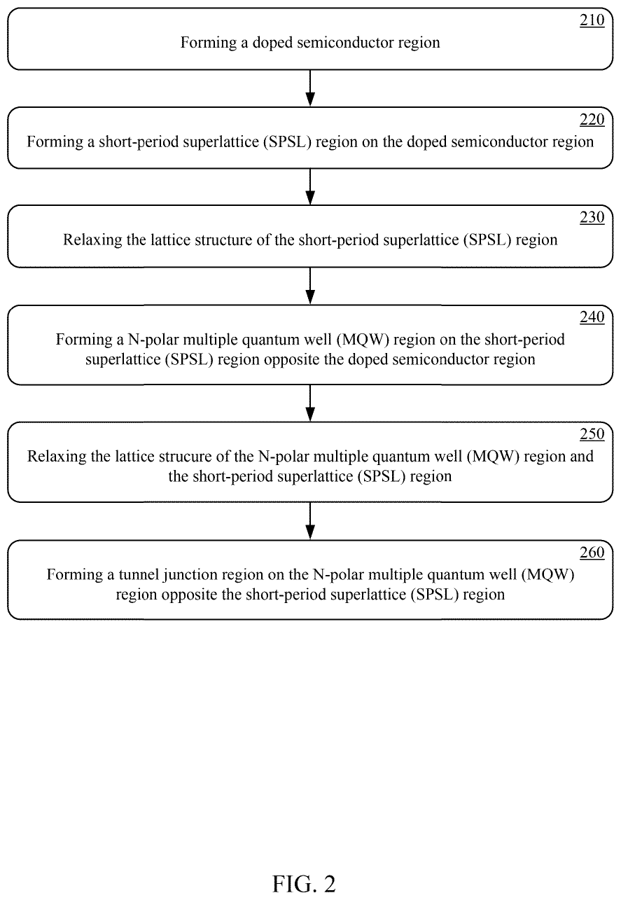

Referring now to FIG. 2, a method of manufacturing the nanowire, in accordance with aspects of the present technology, is shown. The method can include forming the doped semiconductor region, at 210. The semiconductor region can be doped with a first type of dopant. In one implementation, plasma-assisted molecular beam epitaxy (PA-MBE) can be used to grow an approximately 500 nm thick group III-V semiconductor compound having a first dopant type, such as silicone (Si) doped gallium nitride (GaN). The plasma-assisted molecular beam epitaxy (PA-MBE) parameters can be configured to produce a doped semiconductor region with a submicron lateral width. The plasma-assisted molecular beam epitaxy (PA-MBE) parameters can also be configured to produce a doped semiconductor region with a N-polar crystalline lattice structure (e.g., 0001).

At 220, the short period superlattice (SPSL) region can be formed on the doped semiconductor region. In one implementation, plasma-assisted molecular beam epitaxy (PA-MBE) can be used to grow a plurality of periods of atomic monolayers, such as a Si-doped indium gallium nitride (InGaN) layers and gallium nitride (GaN) layers. In one implementation, plasma-assisted molecular beam epitaxy (PA-MBE) parameters can be configured to produce a short period superlattice (SPSL) region with a N-polar crystalline lattice structure (e.g., 0001). The plasma-assisted molecular beam epitaxy (PA-MBE) parameters can also be configured to produce a short period superlattice (SPSL) region, on the doped semiconductor region, with a submicron lateral width substantially the same as the doped semiconductor region. At 230, the lattice structure of the short period superlattice (SPSL) region can be relaxed. In one implementation, an in situ anneal can be performed after forming the short period superlattice (SPSL) region to reduce the density of defects.

At 240, a N-polar multiple quantum well (MQW) region can be formed on the short period superlattice (SPSL) region opposite the doped semiconductor region. In one implementation, the plasma-assisted molecular beam epitaxy (PA-MBE) can be used to grow a plurality of periods of quantum wells (QW) and quantum barriers (QB). The quantum wells can include quantum dots, disks, arches and or the like. In one implementation, plasma-assisted molecular beam epitaxy (PA-MBE) parameters can be configured to produce the multiple quantum well (MQW) region with the N-polar crystalline lattice structure (e.g., 0001). The plasma-assisted molecular beam epitaxy (PA-MBE) parameters can also be configured to produce a multiple quantum well (MQW) region, on the short period superlattice (SPSL) region, with a submicron lateral width substantially the same as the short period superlattice (SPSL) region and the doped semiconductor region. At 250, the lattice structure of the N-polar multiple quantum well (MQW) region can be relaxed. In one implementation, an in situ anneal can be performed after forming N-polar multiple quantum well (MQW) region to reduce the density of defects.

At 260, the tunnel junction region can be formed on the N-polar multiple quantum well (MQW) region opposite the short period superlattice (SPSL) region. The tunnel junction region can be a semiconductor doped with a second type of dopant. In one implementation, plasma-assisted molecular beam epitaxy (PA-MBE) can be used to grow an approximately 260 nm group III-V compound semiconductor having a first dopant type, such a magnesium (Mg) doped (p-type) GaN layer. In one implementation, plasma-assisted molecular beam epitaxy (PA-MBE) parameters can be configured to produce the tunnel junction region with the N-polar crystalline lattice structure (e.g., 0001). The plasma-assisted molecular beam epitaxy (PA-MBE) parameters can also be configured to produce a tunnel junction region, on the multiple quantum well (MQW) region, with a submicron lateral width substantially the same as the multiple quantum well (MQW) region, the short period superlattice (SPSL) region and the doped semiconductor region. The method of manufacturing the nanowire can further include a number of other fabrication processes to not necessary for an understanding of aspects of the present technology, and therefore are not described herein.

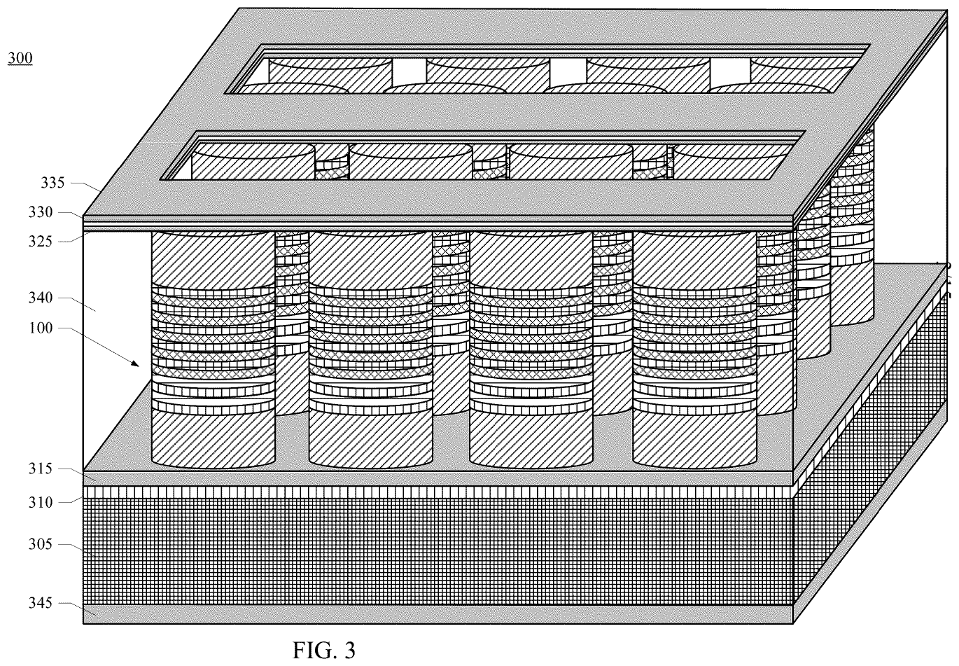

One or more nanowires can be utilized in micro light emitting devices (μLED) in accordance with aspects of the present technology. Referring now to FIG. 3, a micro light emitting device (μLED), in accordance with aspects of the present technology, is shown. The micro light emitting device (μLED) 300 can include a plurality of nanowires 100, as described above, fabricated on a substrate 305. There may also be a number of layers disposed on the substrate 305 that are utilized for the fabrication of the plurality of nanowires 100. For example, there may be one or more nucleation layers 310 disposed the substrate that are configured to promote growth of the nanowires, including by not limited to growth of N-polar doped semiconductor regions 120, short period superlattice (SPSL) regions 110, multiple quantum well (MQW) regions 130 and tunnel junction regions 140. There may also be one or more additional layers, not shown, that are configured to reduce strain, lattice defects and the like in the doped semiconductor regions 120, short period superlattice (SPSL) regions 110, multiple quantum well (MQW) regions 130 and tunnel junction regions 140. There may also be one or more nanopattern mask layers 315 disposed the substrate 305 that are configured to promote selective area growth of the nanowires 100 on portions of the substrate 305 and or nucleation layer 310. The nanowires 100 of the micro light emitting device (μLED) 300 can be arranged in one or more arrays.

The micro light emitting device (μLED) 300 can also include one or more first contacts 325-335 that can be disposed on the plurality of nanowires 110 opposite the substrate 305. In one implementation, a plurality of first contacts 325-335 can be configured to couple to different clusters of nanowires 100. For example, FIG. 3 illustrates a single first contact 325-335 configured to be couple to a cluster of sixteen nanowires 100. The device can include one or more sets of clusters of nanowires 100 with corresponding separate first contacts 250-350. In one implementation, the one or more first contacts 325-335 can include a first layer 325 of Nickle (Ni), Gold (Au) and/or NiAu alloys thereof, a second layer 330 of Indium Tin Oxide (ITO) disposed on the first layer 325 and coupled to the plurality of nanowires 100, and a third layer 335 of Nickle (Ni), Gold (Au) and/or NiAu alloys thereof disposed on the second layer 330. The second layer 330 of ITO can be configured to permit light to pass out the top of the micro light emitting device (μLED) 300. The first and third layers 325, 335 can be configured to make good ohmic contact with the nanowires 310 through the second layer 330, and can include one or more windows to permit light to pass through. The nanowires device 300 can further include an optically transmissive layer 340 disposed about the plurality of nanowires 100 between the substrate 305 and the one or more first contacts 325-335. In one implementation, the optically transmissive layer 340 can be a polyimide. One or more second contacts 345 can be disposed on the substrate 305 opposite the plurality of nanowires 100. The one or more second contacts 345 can be electrically coupled to the nanowires 100 through the substrate 305 and the optional one or more nucleation layers 310 and one or more nanopattern mask layers 315. In one implementation, the one or more second contacts 345 can include one or more layers of Titanium (Ti), Gold (Au) and/or TiAu alloys thereof. The substrate 305 can be a heavily n-doped silicon (Si) substrate to make a good ohmic contact between the second contact 345 and the plurality of nanowires 100. In another implementation one or more of the first contact layers 325-335 may be reflective, and the substrate 305, optional one or more nucleation layers 310, one or more nanopattern mask layers 315 and one or more second contact layers 345 can be transmissive to permit light to be transmitted out the bottom of the micro light emitting device (μLED) 300.

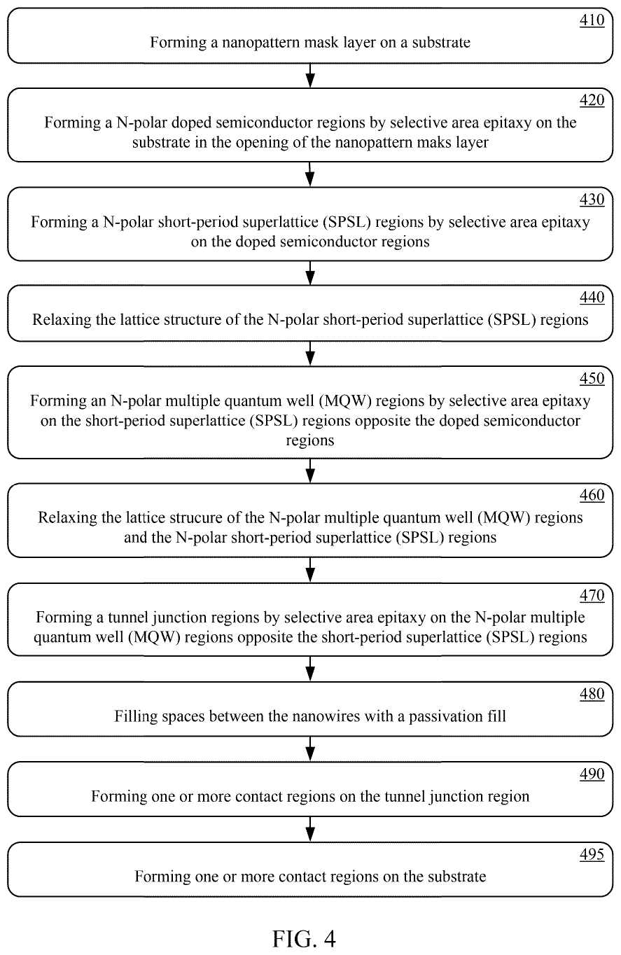

Referring now to FIG. 4, a method of manufacturing a micro light emitting device (μLED), in accordance with aspects of the present technology, is shown. The method of fabrication nanowires can include forming a nanopattern mask on a substrate, at 410. The nanopattern mask fabrication may include nitriding the surface of the substrate, forming a nucleation layer, annealing the nucleation layer, forming an initial N-polar layer, and depositing and patterning a mask layer. In one implementation, the surface of a sapphire (Al₂O₃) or silicon (Si) substrate can be prepared to promote N-polar growth by a nitridation process or an aluminum nitride (AlN) deposition. After the nitridation step is completed, the substrate temperature may be lowered, and an N-polar gallium nitride (GaN) nucleation layer may be deposited. The nucleation layer serves as an intermediate layer between the single-crystalline substrate and the following epitaxial single crystalline gallium nitride (GaN) layers to accommodate in-plane lattice parameter differences existing between substrate and nitride device layers. Alternatively, no nucleation layer may be deposited, and the N-polar gallium nitride (GaN) doped semiconductor region may be deposited directly onto the nitridated sapphire substrate.

A mask material can be applied to the nucleation layer by physical vapor deposition or chemical vapor deposition techniques. In one implementation, a titanium (Ti) layer can be deposited by chemical vapor deposition (CVD). Direct writing of a nanopattern (e.g., electron beam lithography, thermal scanning probe lithography, nanoimprint lithography) or an indirect method (e.g., photolithography, extreme ultraviolet lithography) may be employed. The etching of the mask material can be realized using standard microfabrication techniques, such as reactive ion etching or a lift-off process. For the selective area epitaxy of GaN nanopillars, the nanopattern may include circular or hexagonal openings with a diameter of approximately 50-500 nm and a pitch (e.g., spacing) of approximate 100-600. The pitch between holes is large enough to prevent unwanted coalescence of the nanopillars when accounting for lateral growth. The diameter and pitch of the nanopillars may be designed to promote a photonic crystal effect and the emergence of narrow emission modes. Under optimal conditions, GaN will grow on the exposed initial N-polar GaN layer, but not on the mask, hence the selectivity of the epitaxy process. Examples of mask materials include titanium, to be nitridated to titanium nitride, titanium dioxide, titanium nitride, silicon dioxide, or silicon nitride. In embodiments, a preferred mask material is one that has a low sticking coefficient and high adatom diffusion length, and can withstand high growth temperatures and remain inert to the exposed chemistries in a epitaxy chamber.

At 420, a N-polar doped semiconductor region may be formed by selective area epitaxy in the openings of the nanopattern mask layer. In one implementation, a N-polar gallium nitride (GaN) layer doped with a n-type dopant, such as silicon (Si), can be deposited by plasma-assisted molecular beam epitaxy (PA-MBE). In one implementation, the N-polar GaN semiconductor region can be approximately 400-1000 nm thick. The doping concentration may be uniform through the thickness of the N-polar n-doped GaN layer or may exhibit a step-like doping profile with silicon (Si) concentration increasing in the latter part of the n-type conductive GaN layer. In general, growth conditions for Si-doped N-polar GaN layer is selected to maximize conductivity, i.e., the mathematical product of carrier concentration and electron mobility. The N-polar doped semiconductor region can be beneficial for the growth of the subsequent N-polar short period superlattice (SPSL) region and or the N-polar multiple quantum well (MQW) region. More specifically, it may promote the incorporation of indium (In) atoms leading to higher InN content in the N-polar short period superlattice (SPSL) region and or the N-polar multiple quantum well (MQW) region.

An objective at this stage of the process is to ensure growth of N-polar GaN as hexagonal or circular pillars over the openings in the nanopattern mask layer. Source material arriving on top of the masked portions of the wafer is desorb so that no GaN growth is initiated on these sections of the wafer. A further aspect of the growth at this stage is the bending of threading dislocations possibly penetrating from the substrate towards nano-pillar surfaces. The III-N N-polar nanopillars are expected to be free of structural defects. Growth conditions are selected to favor vertical or axial growth in c-crystallographic direction of N-polar material and limit growth laterally on the pillar sidewalls to avoid coalescence of the nano-pillars at this early stage of the process.

At 430, a short period superlattice (SPSL) region can be formed by selective area epitaxy on the doped semiconductor region opposite the doped semiconductor region. The short period superlattice (SPSL) region can include a plurality of atomic monolayers. In one implementation, 4-10 periods of silicon doped indium gallium nitride (InGaN) layers and gallium nitride layers can be deposited by plasma-assisted molecular beam epitaxy (PA-MBE). In one implementation, the silicon doped indium gallium nitride (InGaN) layers of approximately 8-9 nm thick, and gallium nitride (GaN) layers of approximately 8-15 nm thick. The InN composition of the InGaN layers may range between 10-30%. The InN compositions may react, up to 20% in a single InGaN layer and up to 40% in InGaN layers as part of a superlattice strain relaxation structure. The incorporation of indium (In) into the crystal lattice can be promoted by lowering the growth temperature to between 800-1000° C. The short period superlattice (SPSL) region may preferably be doped with silicon (Si), or remain undoped. Optionally, the lattice structure of the N-polar short period superlattice (SPSL) region can be relaxed, at 440. In one implementation, the nanowires fabricated up to this point can be annealed to relax the lattice structure.

At 450, a N-polar multiple quantum well (MQW) region can be formed by selective area epitaxy on the short period superlattice region opposite the doped semiconductor region. In one implementation, an indium gallium nitride (InGaN) quantum well (QW) of approximately 9 nm thick can be deposited by plasma-assisted molecular beam epitaxy (PA-MBE). A gallium nitride (GaN) quantum barrier (BQ) of approximately 15 nm thick can be deposited by plasma-assisted molecular beam epitaxy (PA-MBE). The process of forming the gallium nitride (InGaN) quantum well (QW) and gallium nitride (GaN) quantum barrier (QB) can be repeated a plurality of times to form between 2-6 periods of interleaved quantum wells (QW) and quantum barriers (QB) in the N-polar multiple quantum well (MQW) region. Optionally, the lattice structure of the N-polar multiple quantum well (MQW) region can be relaxed, at 460. In one implementation, the nanowires as fabricated up to this point can be annealed to relax the lattice structure.

At 470, a tunnel junction region can be formed by selective area epitaxy on the N-polar multiple quantum well (MQW) region opposite the N-polar short period superlattice (SPSL) region. In one implantation, a N-polar GaN tunnel junction region approximately 260 nm thick can be deposited by plasma-assisted molecular beam epitaxy (PA-MBE). The N-polar GaN tunnel junction region can be doped with p-type dopant, such as magnesium (Mg), during epitaxy growth of the n-doped gallium nitride (GaN) region. At 480, spaces between the nanowire can be filled with a passivation fill. In one implementation, aluminum oxide (Al₂O₃) can be deposited by atomic layer deposition (ALD) to fill the spaces between the nanowires.

At 490, one or more contact regions can be formed on the tunnel junction region. In one implementation, a nickel (Ni) layer a gold (Au) layer and an indium tin oxide (ITO) layer, are deposited to form a contact on exposed portions of the tunnel junction region. In addition, a reflected contact pad of silver (Ag), tin (Ti), aluminum (Al), nickel (Ni) and gold (Au) can also be deposited to facilitated light collection from the back of the substrate. At 495, one or more contact regions can also be formed on the substrate. In one implementation, a layer of tin (Ti) and a layer of gold (Au) are deposited to form a contact on the substrate.

The nanowires advantageously achieve strong red emission (>620 nm) from a dislocation free N-polar InGaN/GaN multiple quantum well (MQW) region underlaid with a InGaN/GaN short period superlattice (SPSL) region to reduce strain and incorporate more indium (In) in the N-polar InGaN/GaN multiple quantum well (MQW) region. The resulting submicron scale devices show red electroluminescence dominantly from the N-polar InGaN/GaN multiple quantum well (MQW) region at low to moderate current. Example implementations can advantageously achieve a peak external quantum efficiency (EQE) of approximately 2.2% and a wall-plug efficiency (WPE) of approximately 1.7%. These are among the highest values reported for submicron scale red light emitting devices. Aspects of the present technology therefore advantageously provide a new path to overcome the conventional efficiency bottleneck of red light emitting micro light emitting devices (μLED) for a broad range of applications, including but not limited to mobile displays, wearable electronics, biomedical sensing, ultrahigh speed optical interconnects, and virtual/augmented reality devices.

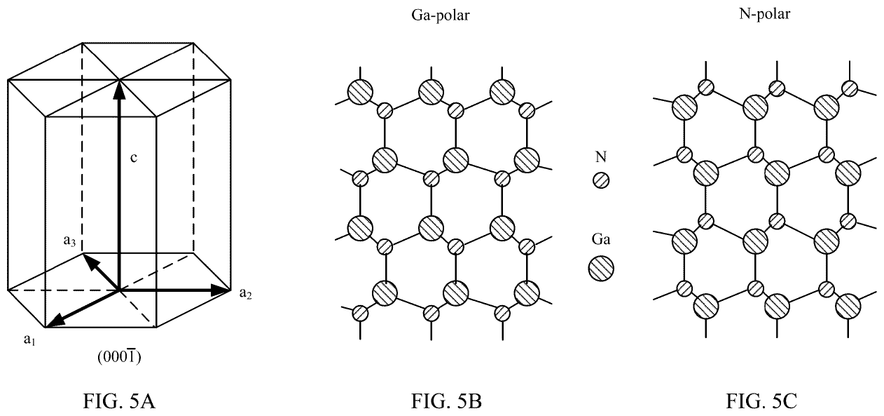

Referring now to FIGS. 5A-5C, semiconductor crystalline structures are shown. FIG. 5A illustrates a hexagonal unit cell. FIG. 5B, illustrates a Ga-polar atomic structure. In the Ga-polar atomic structure, gallium (Ga) atoms terminate the gallium nitride (GaN) semiconductor crystalline structure along the surface. FIG. 5C illustrates a N-polar atomic structure. In the N-polar atomic structure, nitrogen (N) atoms terminate the gallium nitride (GaN) semiconductor crystalline structure along the surface.

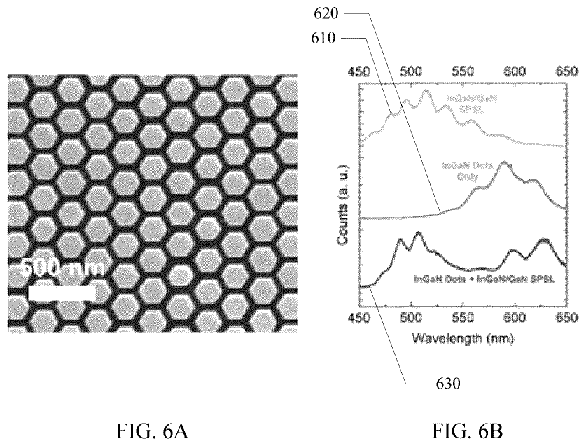

Referring now to FIGS. 6A, an exemplary scanning electron microscope (SEM) image of nanowires, in accordance with aspects of the present technology, is shown. The nanowire image exhibits a uniform morphology and good selectivity. It is seen that such nanowire crystals, with precisely controlled diameter, spacing, polarity and surface morphology, show striking contrasts with previously reported nanowire structures by chemical vapor deposition, or by spontaneous formation. The nanowires shown in this image have diameters of approximately 200 nm, with a pitch of approximately 280 nm. Such nanowire crystals are typically free of dislocations, due to the efficient strain relaxation. In one embodiment, optical properties of a strain engineered N-polar InGaN nanowire heterostructure were examined in detail. Referring now to FIG. 6B a graph of exemplary stacked photoluminescence (PL) spectra of the nanowire samples containing only the InGaN/GaN SPSL, only the InGaN dot active region, and both combined, in accordance with aspects of the present technology, are shown. For a nanowire sample with the incorporation of only InGaN/GaN SPSL, a distinct emission peaking in the green spectrum is measured 610, as shown in FIG. 6B. On the other hand, for nanowire samples with the incorporation of only InGaN dots, the emission is largely limited to the yellow-orange wavelength range 620. The presence of multiple peaks is due to the optical interference associated with the underlying GaN/sapphire substrate. In one embodiment, extensive growth optimization of the InGaN dot active region is performed and a significant reduction of the photoluminescence intensity from the InGaN dots is observed when the emission peak is shifted to the red spectrum (e.g., >620 nm) by further increasing indium incorporation, which is due to the significantly enhanced defect formation in an such indium-rich active region. However, by growing the InGaN dots above the SPSL, a distinct red shift in the emission peak from the dot to 630 nm without any significant degradation of the photoluminescence emission 630 is realized. The presence of a strain engineered InGaN/GaN SPSL can effectively promote strain relaxation within the InGaN dots and enhance indium incorporation, thereby leading to longer wavelength (red) emission. As described previously, these samples were grown with the in-situ annealing steps, which enhances the intensity of the emission from N-polar InGaN/GaN nanowires. It is of note that the red photoluminescence emission intensity of the InGaN dots is comparable to that of the green emission from the SPSL, further confirming the effectiveness of such a strain engineered approach in achieving efficient red emission. The radiative recombination of charge carriers for the μLED device under electrical injection will primarily occur in the red-emitting InGaN dot active region, rather than the green-emitting SPSL, due to the low hole mobility and the built-in fields, to be described next.

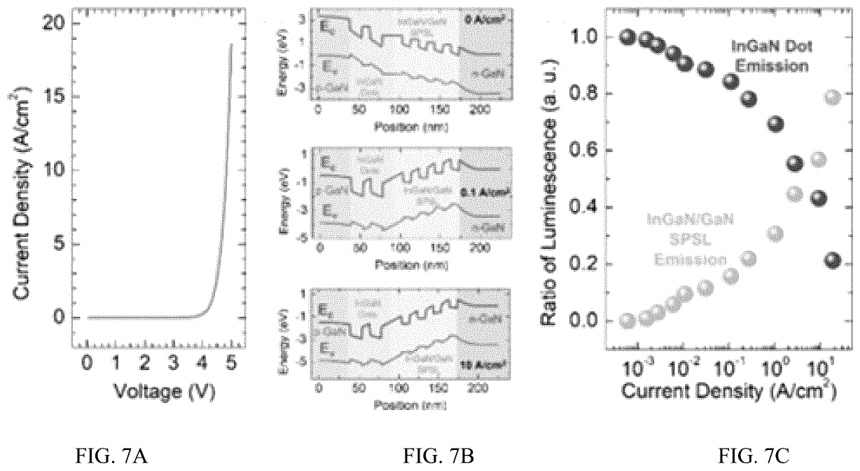

The device structure in accordance with aspects of the present technology was simulated using Silvaco Atlas with standard parameters. In one exemplary implementation, the presence of surface recombination was not considered, and the InGaN layers within the superlattice and the active region was assumed to be 25% of the theoretical values, considering the effects of the thick layers and polarization field screening. The exemplary simulated J-V characteristics are shown in FIG. 7A. The relatively high turn-on voltage is due to the use of a relatively thick active region and the relatively low doping assumed in the superlattice layers. The band diagrams at equilibrium, at a low injection current of approximately 0.1 A/cm2 and a moderate injection current of approximately 10 A/cm2 are calculated and plotted in FIG. 7B. These diagrams show a small barrier to hole injection into the first dot from the p-GaN layer at equilibrium, while at low injection this barrier almost disappears. At higher injections it is possible to inject holes into the superlattice layer as well, resulting in luminescence emission from that layer. The relative ratio of radiative recombination within the InGaN dot active region and the superlattice is further simulated and plotted in FIG. 7C. At lower injection currents the emission is confined to the InGaN dot active region, with almost all the emission originating in the active region. As the current increases, the emission from the superlattice layers starts to increase, and it becomes non-negligible for currents at and above approximately 5 A/cm2. It is also of note that high efficiency N-polar nanowire-based LEDs show a peak in EQE at relatively low injection currents (e.g., <1 A/cm2), which also corresponds to the regime where emission primarily from the red-emitting InGaN dot active region is observed. For applications in the emerging virtual reality, high efficiency, ultralow power, and ultrasmall size LEDs are essentially required. In this regard, the presented design is well suited for such applications. Moreover, the design of the InGaN SPSL and dot active region can be further optimized to achieve predominantly red emission at even higher current densities.

In one embodiment, to fabricate nanowire μLED devices, the gaps in between the wires were filled using atomic layer deposition (ALD) of aluminum oxide Al₂O₃. The aluminum oxide Al₂O₃ on the top of the nanowires was carefully etched using RIE to expose the top p-GaN layer of the nanowires. This was followed by a plasma enhanced chemical vapor deposition (PECVD) of silicon oxide SiO₂ to act as the insulation layer, into which submicron vias were defined by projection lithography. The injection window had a diameter of approximately 0.8 μm, defining the area of the μLED. The silicon oxide SiO₂ in these openings was etched, using RIE, until the nanowires were visible. An SEM image of one such etched device opening, having nanowires with diameter of approximate 125 nm and spacing of approximately 240 nm, is shown in the inset of FIG. 4A in accordance with one embodiment. Tin and Gold Ti/Au metal contacts were then deposited for then-contact, while Ni/Au/ITO was deposited for the p-contact. The devices were then annealed in a forming gas ambient. Finally, a reflective Ag/Ti/Al/Ni/Au contact pad was deposited over the devices to facilitate light collection from the back of the wafer.

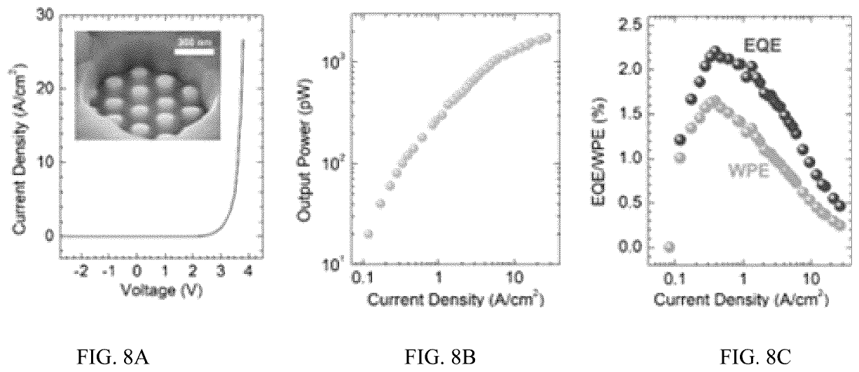

Referring now to FIG. 8A, a graph of exemplary J-V characteristics of a fabricated device, in accordance with aspects of the present technology, is shown. The device was fabricated having a nanowire diameter of approximately 175 nm and a pitch of approximately 360 nm. The device shows negligible leakage current under reverse bias, with excellent rectification. In forward bias, the device shows a turn-on at approximately 3 volts (V). To measure the output power of the device, it was placed directly on a Newport 918D-ST-UV detector and collected the power on-wafer, from the back of the sapphire substrate. The L-I characteristics of the device are shown in FIG. 8B. It is seen that the output power increases with injection current. However, a noticeable change of the slope is observed around 5 A/cm2, which corresponds approximately to the transition from dominantly red emission to green emission (to be described next), in good agreement with the simulation shown in FIG. 7C. The corresponding external quantum efficiency (EQE) and wall-plug efficiency (WPE) plots for the device are shown in FIG. 8C. A peak EQE of approximately 2.2% and WPE of approximately 1.7% were achieved at a current density of ˜0.4 A/cm². This is a higher EQE than typical conventional attempts at a red emitting (>620 nm) μLED with lateral dimensions on the order of 1 μm, or less. It is also noticed that there is a significant efficiency droop, which can be minimized by further optimizing the design and by incorporating an AlGaN electron blocking layer. The insert in FIG. 4A shows a SEM image of a μLED device injection opening that has been etched into the silicon oxide (SiO₂) insulation layer.

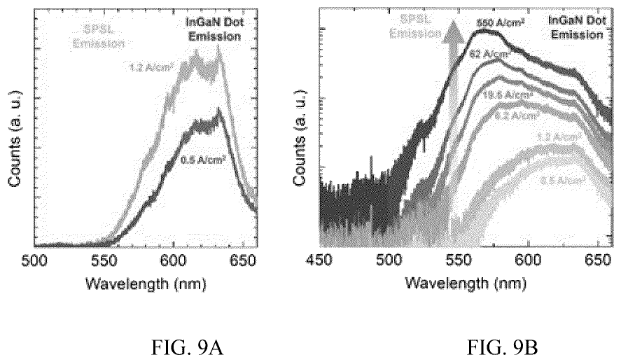

The variation of the electroluminescence with injection current can also be examined. Referring now to FIG. 9A, a graph plot of an exemplary electroluminescence spectra for a device measured at different injection currents, in accordance with aspects of the present technology, is shown. At low injection currents of around 1 A/cm² and less, the emission peaks at approximately 630 nm, putting it in the red region of the visible spectrum. However, as the injection current increases, the emission at approximately 570 nm starts to dominate the spectrum, making the emission appear more orange/amber. The peak at approximately 570 nm is related to parasitic emission from the SPSL in this sample, whereas the longer wavelength emission at approximately 630 nm originates from the InGaN dot active region. When the injection current is increased even further, as shown in FIG. 9B, the SPSL emission becomes the primary peak, making the device emission appear yellow. The emission from the dots appears as a shoulder at approximately 620 nm at high injection currents, and the position of this emission does not show much change with injection current. This is likely due to the efficient strain relaxation in the active region induced by the growth of the SPSL. The reduced strain in the active region minimizes the effect of the QCSE, allowing for stable emission.

In one embodiment, the use of thick InGaN and superlattice structures underlying an InGaN-based active region has been demonstrated to release strain within the active region, resulting in red-shifted emission wavelengths for conventional quantum well LEDs. In one exemplary implementation, within planar LED heterostructures, a relatively thick buffer or superlattice layer is utilized in order to effectively relax strain, and the relative mismatch between the layers needs to be minimized to prevent the generation of extensive defects, thereby preventing the realization of efficient red LEDs. In one embodiment, for planar structures, the use of thermal annealing effectively relaxes InGaN buffer layers, however the surface morphology was characterized by large pits. As such, in one exemplary implementation red LEDs demonstrated using these processes show very low efficiencies. In one exemplary implementation, these issues can be fundamentally addressed in nanowires, allowing for extremely effective strain relaxation even with a thin superlattice stack, making it much easier to attain red emission. In one embodiment this technique relies only on epitaxy, avoiding regrowth and extra processing steps that can be difficult to control in other methods, such as making the substrate porous. It also retains the advantages of nanowire processing, namely the avoidance of a mesa etch step during the fabrication of μLEDs. These factors have contributed to the demonstration of a red-emitting submicron scale LED with an external quantum efficiency>2%, for the first time.

In one embodiment, an InGaN/GaN SPSL is incorporated into a red-emitting N-polar nanowire heterostructure, to achieve red emission. With this unique design, submicron scale LEDs with emission at approximately 630 nm, and a peak EQE of 2.2% for an unpackaged device is demonstrated. In one exemplary implementation, the electroluminescence of the devices shows a negligible change in the emission wavelength of the InGaN active region peak with increasing injection current, because of the efficient strain relaxation in the active region which inhibits QCSE. The issues of spectral purity and extraneous emissions at higher currents can be minimized through improvements in the design of the LED heterostructure devices, which can effectively limit recombination to the active region. This shows the promise of the nanowire-based approach for high efficiency μLEDs.

In one embodiment, light emitting device can emit photons (e.g., light, radiation, etc.). In one exemplary implementation, light emitting device emits light. In one embodiment, the p doped layer, intermediate active region, and n doped region are configured to emit light. Light can be emitted in the ultra violet range. Light can be emitted in a wavelength of approximately 210 nm to 260 nm. Light can be emitted with a wavelength of approximately 255 nm, plus or minus 5 nanometers.

The N-polar growth of GaN, InGaN, and the like, results in a nanowire having a flat planar surface. The flat planar surface is more conducive to multi-quantum well structures that have less leakage current, are better defined, and reduced edge and/or middle effects. The growth of N-polar semiconductors is impacted by the choice of substrate and its surface conditions, initial nitridation of the substrate to form a nitrogen-rich surface, the use of a suitable nucleation or buffer layer, the avoidance of inversion domain defects at the initial stage of growth, and the maintenance of the N-polar GaN or InGaN growth orientation as the layer is deposited.

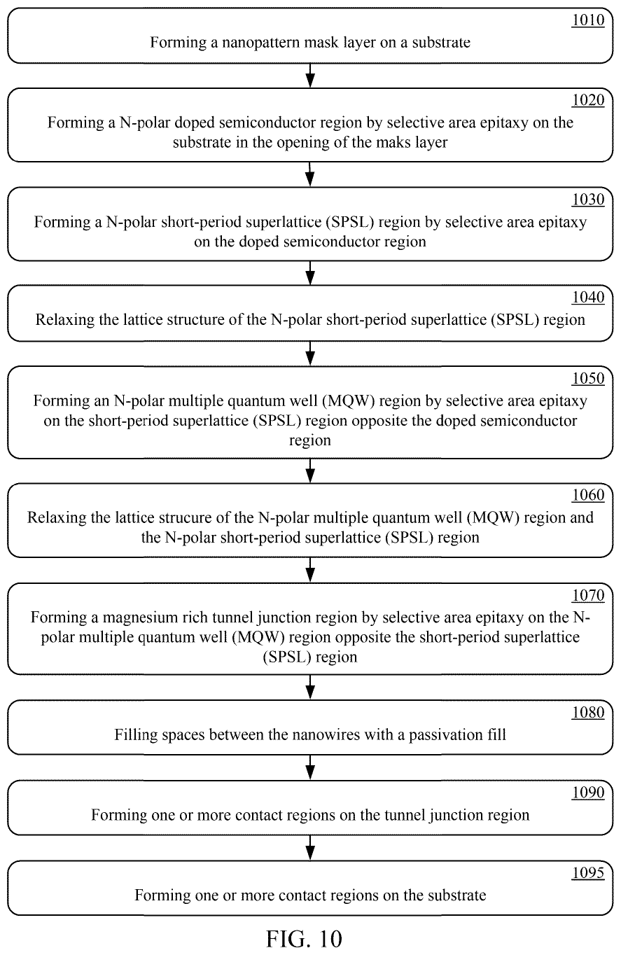

Referring now to FIG. 10, a method of manufacturing a micro light emitting device (μLED), in accordance with aspects of the present technology, is shown. The method of fabrication nanowires can include forming a nanopattern mask on a substrate, at 1010. The nanopattern mask fabrication may include nitriding the surface of the substrate, forming a nucleation layer, annealing the nucleation layer, forming an initial N-polar layers, and depositing and patterning a mask layer. In one implementation, the surface of a sapphire (Al₂O₃) or silicon (Si) substrate can be prepared to promote N-polar growth by a nitridation process. The nucleation layer serves as an intermediate layer between the single-crystalline substrate and the following epitaxial single crystalline gallium nitride (GaN) layers to accommodate in-plane lattice parameter differences existing between substrate and nitride device layers. Alternatively, no nucleation layer may be deposited, and the N-polar gallium nitride (GaN) doped semiconductor region may be deposited directly onto the nitridated sapphire substrate.

A mask material, such as titanium, can be applied to the nucleation layer by physical vapor deposition or chemical vapor deposition techniques. Direct writing of a nanopattern (e.g., electron beam lithography, thermal scanning probe lithography, nanoimprint lithography) or an indirect method (e.g., photolithography, extreme ultraviolet lithography) may be employed. The etching of the mask material can be realized using standard microfabrication techniques, such as reactive ion etching or a lift-off process. For the selective area epitaxy of GaN nanopillars, the nanopattern may include circular or hexagonal openings with a diameter of approximately 50-500 nm and a pitch (e.g., spacing) of approximate 100-600. The pitch between holes is large enough to prevent unwanted coalescence of the nanopillars when accounting for lateral growth. The diameter and pitch of the nanopillars may be designed to promote a photonic crystal effect and the emergence of narrow emission modes. Under optimal conditions, GaN will grow on the exposed initial N-polar GaN layer, but not on the mask, hence the selectivity of the epitaxy process. Examples of mask materials include titanium, to be nitridated to titanium nitride, titanium dioxide, titanium nitride, silicon dioxide, or silicon nitride. In embodiments, a preferred mask material is one that has a low sticking coefficient and high adatom diffusion length, and can withstand high growth temperatures and remain inert to the exposed chemistries in a epitaxy chamber.

At 1020, a N-polar doped semiconductor region may be formed by selective area epitaxy in the openings of the nanopattern mask layer. In one implementation, a N-polar GaN semiconductor region can be of approximately 400-1000 nm thick deposited by plasma-assisted molecular beam epitaxy (PA-MBE). The N-polar GaN semiconductor layer can be doped with n-type dopant, such as silicon (Si), during epitaxy growth. The doping concentration may be uniform through the thickness of the N-polar n-doped GaN layer or may exhibit a step-like doping profile with silicon (Si) concentration increasing in the latter part of the n-type conductive GaN layer. In general, growth conditions for Si-doped N-polar GaN layer is selected to maximize conductivity, i.e., the mathematical product of carrier concentration and electron mobility. The N-polar doped semiconductor region can be beneficial for the growth of the subsequent N-polar short period superlattice (SPSL) region and or the N-polar multiple quantum well (MQW) region. More specifically, it may promote the incorporation of indium (In) atoms leading to higher InN content in the N-polar short period superlattice (SPSL) region and or the N-polar multiple quantum well (MQW) region.

An objective at this stage of the process is to ensure growth of N-polar GaN as hexagonal or circular pillars over the openings in the nanopattern mask layer. Source material arriving on top of the masked portions of the wafer is desorb so that no GaN growth is initiated on these sections of the wafer. A further aspect of the growth at this stage is the bending of threading dislocations possibly penetrating from the substrate towards nano-pillar surfaces. The III-N N-polar nanopillars are expected to be free of structural defects. Growth conditions are selected to favor vertical or axial growth in c-crystallographic direction of N-polar material and limit growth laterally on the pillar sidewalls to avoid coalescence of the nano-pillars at this early stage of the process.

At 1030, a short period superlattice (SPSL) region can be formed by selective area epitaxy on the doped semiconductor region opposite the doped semiconductor region. The short period superlattice (SPSL) region can include a plurality of atomic monolayers. In one implementation, 4-10 periods of silicon doped indium gallium nitride (InGaN) layers and gallium nitride layers. The silicon doped indium gallium nitride (InGaN) layers of approximately 8-9 nm thick, and gallium nitride (GaN) layers of approximately 8-15 nm thick, can be deposited by plasma-assisted molecular beam epitaxy (PA-MBE). The InN composition of the InGaN layers may range between 10-30%. The InN compositions may react, up to 20% in a single InGaN layer and up to 40% in InGaN layers as part of a superlattice strain relaxation structure. The incorporation of indium (In) into the crystal lattice is promoted by lowering the growth temperature to between 800-1000° C. The short period superlattice (SPSL) region may preferably doped with silicon (Si), or remain undoped. Optionally, the lattice structure of the N-polar short period superlattice (SPSL) region can be relaxed, at 1040. In one implementation, the nanowires fabricated up to this point can be annealed to relax the lattice structure.

At 1050, a N-polar multiple quantum well (MQW) region can be formed by selective area epitaxy on the short period superlattice region opposite the doped semiconductor region. In one implementation, an indium gallium nitride (InGaN) quantum well (QW) approximately 9 nm thick can be deposited by plasma-assisted molecular beam epitaxy (PA-MBE). A gallium nitride (GaN) quantum barrier (BQ) approximately 15 nm thick can be deposited by plasma-assisted molecular beam epitaxy (PA-MBE). The process of forming the gallium nitride (InGaN) quantum well (QW) and gallium nitride (GaN) quantum barrier (QB) can be repeated a plurality of times to form between 2-6 periods of interleaved quantum wells (QW) and quantum barriers (QB) in the N-polar multiple quantum well (MQW) region. Optionally, the lattice structure of the N-polar multiple quantum well (MQW) region can be relaxed, at 1060. In one implementation, the nanowires as fabricated up to this point can be annealed to relax the lattice structure.

At 1070, a magnesium rich tunnel junction region can be formed by selective area epitaxy on the N-polar multiple quantum well (MQW) region opposite the N-polar short period superlattice (SPSL) region. In one implantation, a N-polar GaN tunnel junction region approximately 260 nm thick can be deposited by plasma-assisted molecular beam epitaxy (PA-MBE). The N-polar GaN tunnel junction region can be doped with p-type dopant, such as magnesium (Mg), during epitaxy growth of the n-doped gallium nitride (GaN) region.

At 1080, spaces between the nanowire can be filled with a passivation fill. In one implementation, aluminum oxide (Al₂O₃) can be deposited by atomic layer deposition (ALD) to fill the spaces between the nanowires.

At 1090, one or more contact regions can be formed on the tunnel junction region. In one implementation, a nickel (Ni) layer, a gold (Au) layer and an indium tin oxide (ITO) layer, are deposited to form a contact on exposed portions of the tunnel junction region. In addition, a reflected contact pad of silver (Ag), tin (Ti), aluminum (Al), nickel (Ni) and gold (Au) can also be deposited to facilitated light collection from the back of the substrate. At 1095, one or more contact regions can also be formed on the substrate. In one implementation, a layer of tin (Ti) and a layer of gold (Au) are deposited to form a contact on the substrate.

In the conventional art, the achievement of efficient p-type doping of GaN, using Mg as an acceptor, in the early 1990s by Nakamura et al was a fundamental piece of the puzzle that led to a revolution in lighting and display technologies that is going on even today. However, while highly efficient blue and white light sources with large areas are available, traditionally the efficiency of small-area devices and devices with ultraviolet or long wavelength emission remain quite low. The relatively inefficient conventional p-type doping of GaN has been attributed as a major factor for the low efficiency, being limited by the high Mg acceptor ionization energy, low Mg solubility, and the tendency to form compensating defects. The low free holes in these materials of traditional approaches can also increase the effects of electron leakage from the active region, causing an unwanted emission peak and reducing efficiency, especially at higher injection currents. This problem is made even worse in the case of conventional top-down micro light emitting devices (μLED) where a plasma etch is typically used to define the device injection mesa. This etching process results in severe surface damage along the sidewalls of the mesa, which leads to increased non-radiative and surface recombination. The leakage current in micro light emitting devices (μLED) depends critically on the surface states formed due to the plasma etching process, as they provide centers for Shockley-Read-Hall (SRH) non-radiative recombination. The larger capture cross-section of holes at these sites makes them more likely to be trapped at the sidewalls defects, reducing their concentration in the active region of devices. Top-down fabricated micro light emitting devices (μLED) also show a higher current density, at similar voltages, compared to conventional broad area devices, albeit with significantly reduced efficiency and output power density. While the output power density depends on factors such as light extraction, which is expected to be higher for smaller area light emitting device, the higher current density has been attributed to the increased leakage current, as well as reduced resistances due to the smaller volume of the devices. Traditionally, the compensating effect of dry etching on p-type GaN, whereby the etched surfaces show higher contact resistance and lower hole conductivities due to the formation of shallow dopants at and near the surface.

Nanostructures have been shown to improve the p-type doping of the III-nitrides, by enabling defect-free and strain-relaxed crystals. The bottom-up growth process is compatible with fabrication techniques where the device active region is not directly exposed to plasma, so the impact of surface recombination can be greatly reduced. The formation of a core-shell structure spontaneously during growth can further reduce the contribution of recombination at the sidewalls. In one embodiment, Mg-doping of InN, GaN and AlN nanowires grown by plasma-assisted molecular beam epitaxy (MBE) show a significantly reduced formation energy for substitutional Mg dopant incorporation due to the reduced strain distribution, resulting in a higher Mg concentration and reduced compensating defect formation compared to conventional epilayer structures. The III-nitride nanostructures can also be grown in the N-polar orientation, wherein the polarization fields are reversed as compared to the typically used metal-polar orientation. The use of N-polar structures has been shown to be beneficial for mitigating the efficiency droop.

However, previous work has suggested that the Mg doping of N-polar GaN is quite difficult, requiring significantly greater dopant supply during epitaxy to get a similar Mg concentration. In addition, the incorporation of compensating impurities, such as oxygen, is enhanced for N-polar GaN, which further reduces the free hole concentration. The fabrication of nanostructure-based devices is also quite challenging due to the non-planar nature of the surface, making it difficult to reliably obtain high performance devices. As such, there have been no systematic studies on the effect of Mg doping on the performance of nanowire micro light emitting devices (μLED), especially those operating at long wavelengths.

Aspects of the present technology achieve high efficiency submicron scale red light emitting devices. In one embodiment, the devices include N-polar InGaN/GaN nanowire arrays. In one exemplary implementation, the effect of Mg flux is utilized, wherein magnesium Mg is incorporated within the p-GaN layer in N-polar red emitting nanostructure micro light emitting devices (μLED). A pronounced change in device characteristics with increasing Mg flux can be observed, seeing a decrease in leakage current and a significant increase in efficiency. In one embodiment, at the highest Mg flux used, a peak external quantum efficiency of approximately 8.3% can be measured for a micro light emitting device (μLED) having an area approximate 750 nm×750 nm, which is the highest value reported for a red-emitting LED with lateral dimensions around 1 μm, or less. In one exemplary implementation, surface recombination is not the only challenge in fabricating micro light emitting devices (μLED); the p-doping of the GaN contact layer is also crucial for the development of high-efficiency devices.

In one embodiment, nanostructure devices are grown using selective area growth (SAG) on N-polar GaN-on-sapphire substrates, as has been described previously. Firstly, an approximate 500 nm thick Si-doped GaN layer is grown at a high substrate temperature of approximately 960° C. to prevent unwanted growth of GaN on the Ti mask. Then, the temperature is reduced to for the growth of an InGaN/GaN short period superlattice (SPSL) including four periods of approximately 8 nm InGaN and approximately 8 nm GaN. The SPSL has been previously demonstrated to efficiently relax strain within the InGaN layers and help to more easily attain red emission. Subsequently, the growth temperature is further reduced for the growth of the InGaN active region, including a thick InGaN segment having approximately 15 nm thickness. After growing a approximately 30 nm undoped GaN buffer layer at low temperature, the substrate temperature is then increased for the growth of the p-GaN layer. In one embodiment, the Mg acceptor beam flux monitor (BFM) pressure is varied for different samples grown under otherwise identical conditions. Referring to them as Samples A and B, the Mg flux used in the p-doped layer is approximately 5×10⁻⁸ Torr and approximate 5×10⁻⁹ Torr, respectively. For reference, a GaN epilayer grown with a similar growth rate and Mg flux of 5×10⁻⁸ Torr had an Mg atom concentration of approximately 1020 cm⁻³, as measured by secondary ion mass spectroscopy (SIMS).

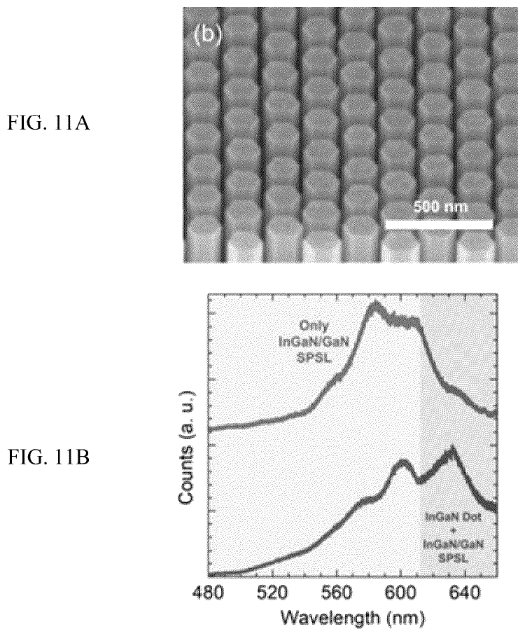

In one embodiment, the grown N-polar nanowires show a flat top surface and smooth sidewalls, shown in the scanning electron microscope (SEM) image in FIG. 11A, confirming the N-polar crystal orientation. There is little lateral growth of the nanowires, even with the high Mg flux, unlike in Ga-polar p-GaN, where too much Mg leads to broadening of the nanowires and degradation in morphology. In one exemplary implementation, a 405 nm laser is used, focused to a spot approximately 30 μm in diameter, to optically excite different nanowire structures. The photoluminescence (PL) spectrum of representative nanostructure arrays containing only the InGaN/GaN SPSL is shown in FIG. 11B in accordance with one embodiment, with dominant emission in the green wavelengths. With the incorporation of an additional InGaN segment, strong red emission can be clearly observed, shown in FIG. 11B in accordance with one embodiment. The multiple peaks seen in the PL spectra are a contribution of the relative inhomogeneity of indium (In) distribution in the active region, as well as the presence of Fabry-Perot modes. While the position of the superlattice peak remains relatively invariant, the red emission at approximately 640 nm becomes noticeably stronger when the InGaN dot is grown. This emphasizes the importance of the SPSL in attaining long-wavelength emission, through the relaxation of strain.

In one embodiment, micro light emitting devices (μLED) A and B are fabricated on the grown nanowire samples. To fabricate the devices in the nanowire arrays, atomic layer deposition (ALD) is used to coat the nanowires with approximately 65 nm of aluminum oxide (Al₂O₃). In one embodiment, the use of ALD for passivation helps recover surface damage after plasma etching, and although this step is not needed for bottom-up nanostructures, the gap in between them can be effectively filled using insulating films deposited with ALD, blocking electrical short paths. A fluorine-based reactive ion etch (RIE) recipe can be used to etch the aluminum oxide (Al₂O₃) from the top of the wires, until the top p-GaN layer is revealed. Plasma enhanced chemical vapor deposition (PECVD) is then used to deposit an approximately 500 nm thick silicon oxide (SiO₂) layer over the nanowires. Following that, sub-micron vias with areas approximately 750 nm×750 nm are defined using lithography and the insulator in the opened injection windows is etched again using reactive ion etching (RIE). Previous work has shown that the penetration depth of ions by etching is of the order of approximately 10-100 nm, depending on the plasma conditions. Therefore, it is expected that the compensation of the p-GaN induced by dry etching will be significant. Metal contacts are then deposited where a Ti/Au (20 nm/100 nm) stack is used as then contact and a Ni/Au/ITO (5 nm/5 nm/200 nm) stack is deposited as the p-contact. In one embodiment, contact annealing is done 450° C. for 1 minute in a forming gas ambient. Finally, a reflective metal contact including Ag/Ti/Al/Ni/Au (100 nm/20 nm/100 nm/20 nm/50 nm) is deposited over the device injection windows to maximize light extraction from the bottom sapphire surface.

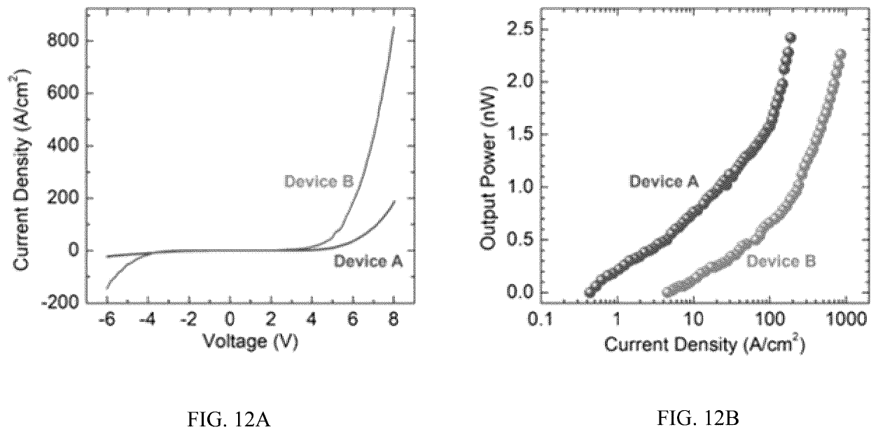

In one embodiment, the fabricated devices are characterized by measuring exemplary JV curves, shown in FIG. 12A. Device B shows a higher forward current and reverse current as compared to Device A. The output power from the device can be measured through the sapphire substrate using a calibrated Newport ST918D-ST-UV detector placed under the sample, which is mounted on the detector using index-matching fluid. Plotted in FIG. 12B are exemplary L-I characteristics for device A and B, where a great increase in output power is measured at similar current densities for the device with the higher Mg doping. These results indicate that the higher Mg doping results in a lower forward leakage current and simultaneously increased output power at similar voltages. As mentioned previously, the plasma etching processes typically used for defining device mesas result in damage to the crystal along the mesa sidewalls, which can contribute to a leakage current that greatly diminishes device performance. This is shown through poorer efficiencies and higher currents in devices with smaller areas. Although in one embodiment, the active region is protected from plasma damage, the top surface of the nanowires will inevitably be etched by it. The higher current measured for Device B is expected due to the greater impact of compensation induced by the plasma etching, because the Mg incorporation is already low. As the hole injection to the active region in this device is lower than Device A, the compensated shallow donors can contribute to the formation of parallel resistance paths, which have a greater contribution to the device current at low voltages, close to the turn-on voltage. The etching process also creates deep traps within the layers that can enhance tunneling leakage current. Previous work on red-emitting micro light emitting devices (μLED) has demonstrated, through detailed temperature dependent measurements, that the transport and recombination of carriers through trap states plays an important role on device performance. The excess current drawn through the leakage paths also contributes to the slightly earlier turn-on voltage for Device B as compared to Device A. Therefore, while surface recombination can be effectively minimized using this bottom-up approach, in one embodiment the degradation of the p-type layer is another major cause of concern for achieving efficient micro light emitting devices (μLED).

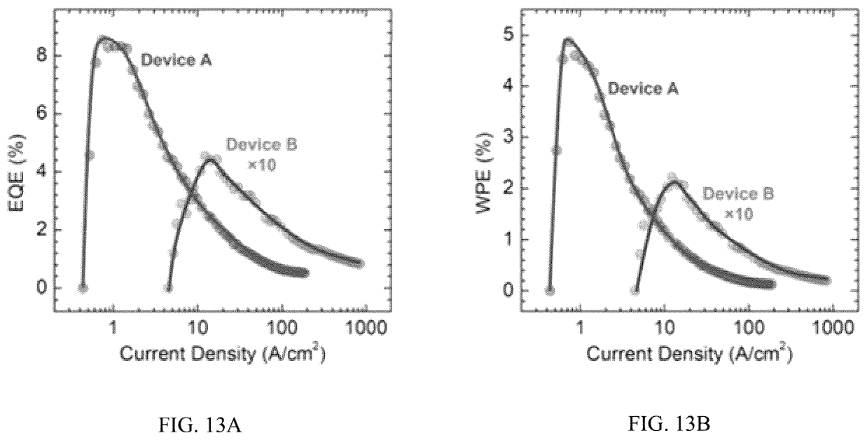

In one embodiment, measured exemplary EQE and WPE for the devices at different injection currents are plotted in FIGS. 13A and 13B, respectively. The peak of the EQE increases and shifts to lower currents with increasing Mg flux. With the high Mg incorporation in Device A, a maximum EQE of approximately 8.3% at a current density of approximately 1 A/cm² is measured. The higher efficiency, and lower current density corresponding to the efficiency peak in Device A is a consequence of the improved hole injection into the device active region and reduced current leakage. Also, both devices show their peak efficiency at relatively low injection currents, with a sharp efficiency droop, consistent with low SRH recombination. This indicates that while the injection of carriers may be compromised in Device B with a lower Mg doping, both devices still have low surface recombination. Devices A and B also exhibit a strong efficiency droop when current is increased, likely due to the effects of carrier transport and recombination in different sections of the active region in the nanowires, which are a result of the complex geometry and concentration profiles within them.

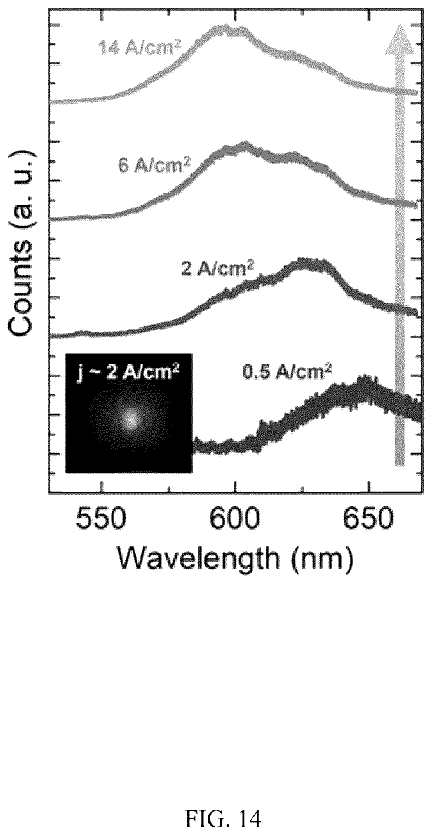

Referring now to FIG. 14, an exemplary normalized electroluminescence (EL) spectra for Device A at injection currents from approximately 0.5 A/cm² up to 14 A/cm², in accordance with aspects of the present technology. At the current approximately 0.5 A/cm², the spectrum exhibits an emission peak of approximately 650 nm. An optical microscope image of the device under operation is included in the inset of the figure, showing bright red emission even for a sub micrometer scale device. From the spectra measured at higher injection currents, it is seen that the emission remains red, with emission peak longer than 600 nm up to a current density around 10 A/cm². This makes them well-suited for red micro light emitting device (μLED) applications, which typically require low current densities of approximately 1-10 A/cm². The current density corresponding to the peak of the measured EQE is similar to the current at which there is a blueshift in the emission peak, suggesting that there is a difference in the nature of radiative recombination at higher injection. This might be related to the complex geometry and doping profiles in nanowire devices. The strong blue-shift at higher injection currents is likely a combination of the quantum-confined Stark effect, as well as from the increased contribution of the SPSL in device emission.

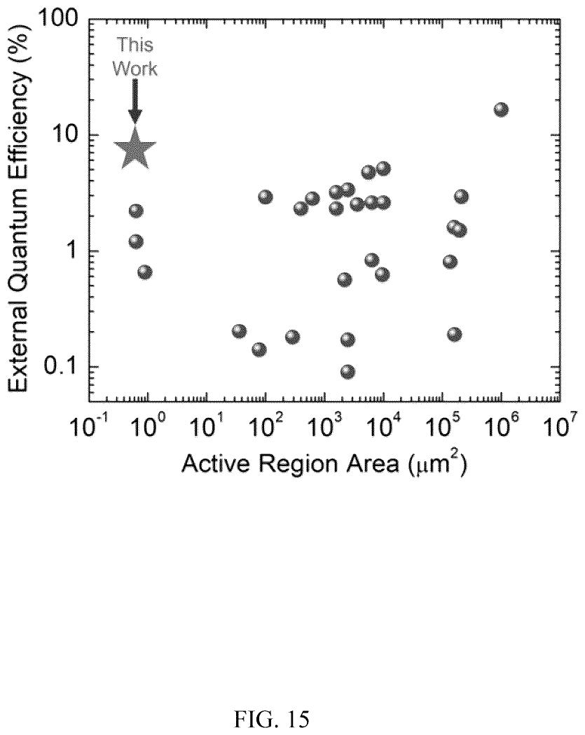

In one embodiment, the effect of Mg doping on the performance of red-emitting N-polar bottom-up micro light emitting device (μLED) is analyzed. By varying the Mg incorporation over an order of magnitude, a marked difference in the J-V curves and efficiency from the devices is demonstrated. In one exemplary implementation, this indicates that the primary limiting factor responsible for the efficiency cliff of micro light emitting devices (μLED) is a combination of both surface recombination current and poor p-type conduction due to etch-induced defects and damage. In one embodiment, the presented novel bottom-up systems and methods approach demonstrate the damage caused to the active region sidewalls can be circumvented, however the p-GaN layer is still strongly affected by compensation, leading to current leakage. In one embodiment, such a critical challenge is efficiently and effectively addressed by significantly increasing Mg-dopant incorporation in the pGaN contact layer. While such an approach/scheme can, in principle, be applied to micro light emitting devices (μLED) in general, the use of nanostructures offers several critical advantages, including significantly enhanced Mg dopant incorporation due to the efficient strain relaxation and the use of N-rich epitaxy conditions to suppress the formation of Nvacancy related defects. In one embodiment, through optimization of the Mg doping within the nanowires, the deleterious effect of the plasma damage on the contact can be diminished, resulting in an increase in device efficiency by over an order of magnitude, as compared to a device with low Mg doping. In one exemplary implementation the high peak EQE measured for the highly doped device is plotted in FIG. 15, along with measured values for red-emitting InGaN LEDs having different active region injection areas. The heavy Mg doping of the optimized device enabled record efficiencies from red-emitting submicron LEDs having an emission wavelength at approximately 650 nm, with a peak EQE and WPE of approximately 8.3% and 4.6%, respectively. This work highlights the critical importance of improving carrier injection for realizing efficient micro light emitting devices (μLED) and presents a novel approach of doing so by increasing the acceptor dopant incorporation.

The foregoing descriptions of specific embodiments of the present technology have been presented for purposes of illustration and description. They are not intended to be exhaustive or to limit the present technology to the precise forms disclosed, and obviously many modifications and variations are possible in light of the above teaching. The embodiments were chosen and described in order to best explain the principles of the present technology and its practical application, to thereby enable others skilled in the art to best utilize the present technology and various embodiments with various modifications as are suited to the particular use contemplated. It is intended that the scope of the invention be defined by the claims appended hereto and their equivalents.

What is claimed is:

1. A light emitting device comprising:
a short period superlattice (SPSL) region of a nanowire; and
a multiple quantum well (MQW) region of the nanowire, wherein the multiple quantum well (MQW) region is disposed on the short period superlattice (SPSL) region.

2. The light emitting device of claim 1, wherein the short period superlattice (SPSL) region reduces crystalline lattice strain in the multiple quantum well (MQW) region.

3. The light emitting device of claim 1, wherein the light emitting device emits red light.

4. The light emitting device of claim 1, wherein the multiple quantum well (MQW) region comprises a N-polar multiple quantum well (MQW) region.

5. A light emitting device including one or more nanowires, each nanowire comprising:
a semiconductor region having a first doping type;
a short period superlattice (SPSL) region disposed on the semiconductor region having the first doping type; and
a N-polar multiple quantum well (MQW) region disposed on the short period superlattice (SPSL) region opposite the semiconductor region having the first doping type.

6. The light emitting device of claim 5, wherein a width of each nanowire is less than one micrometer.

7. The light emitting device of claim 6, wherein a pitch between nanowires is less than one micrometer.

8. The light emitting device of claim 5, further comprising:
a tunnel junction region having a second doping type disposed on the N-polar multiple quantum well (MQW) region opposite the short period superlattice (SPSL) region.

9. The light emitting device of claim 8, wherein:
the semiconductor region having the first doping type comprises a silicon (Si) doped gallium nitride (GaN) region;
the short period superlattice (SPSL) region comprises interleaved atomic monolayers of m indium gallium nitride (InGaN) layers and n gallium nitride (GaN) layers; and
the N-polar multiple quantum well (MQW) region comprises a plurality of interleaved indium gallium nitride (InGaN) quantum wells (QW) and gallium nitride (GaN) quantum barriers (QB); and
the tunnel junction region having the second doping type comprises a magnesium (Mg) doped gallium nitride (GaN) region.

10. The light emitting device of claim 9, wherein:
the silicon (Si) doped gallium nitride (GaN) region is approximately 400-100 nanometers (nm) thick;
the indium gallium nitride (InGaN) layers of the short period superlattice (SPSL) region are approximately 9 nm thick;
the gallium nitride (GaN) layers of the short period superlattice (SPSL) region are approximately 15 nm thick;
the indium gallium nitride (InGaN) quantum wells (QW) are approximately 15 nm thick;
the gallium nitride (GaN) quantum barriers (QB) are approximately 30 nm thick; and
the (Mg) doped gallium nitride (GaN) region is approximately 260 nm thick.

11. The light emitting device of claim 9, wherein the short period superlattice (SPSL) region comprises three to seven indium gallium nitride (InGaN) layers and three to seven gallium nitride (GaN) layers.

12. The light emitting device of claim 8, wherein:
the semiconductor region having the first doping type comprises a N-polar semiconductor region having the first doping type;
the short period superlattice (SPSL) region comprises a N-polar short period superlattice (SPSL) region; and
the tunnel junction region comprises a N-polar tunnel junction region.

13. The light emitting device of claim 5, wherein the one or more nanowires emit red light with a peak external quantum efficiency (EQE) of 2% or greater, and a wall-plug efficiency (WPE) of 1.5% or greater.

14. A method of manufacturing a micro light emitting device (μLED) including a plurality of nanowires, each nanowire comprising:
epitaxially depositing a doped semiconductor region;
epitaxially depositing a short period superlattice (SPSL) region on the doped semiconductor region; and
epitaxially depositing a N-polar multiple quantum well (MQW) region on the short period superlattice (SPSL) region opposite the doped semiconductor region.

15. The method of manufacturing the micro light emitting device (μLED) according to claim 14, further comprising:
relaxing a lattice structure of the short period superlattice (SPSL) region; and
relaxing a lattice structure of the N-polar multiple quantum well (MQW) region.

16. The method of manufacturing the micro light emitting device (μLED) according to claim 14, further comprising:
forming a nanopattern mask layer on a substrate; and
forming the doped semiconductor regions on the substrate in the openings of the nanopattern mask layer.

17. The method of manufacturing the micro light emitting device (μLED) according to claim 14, wherein:
epitaxially depositing the doped semiconductor region includes forming a N-polar silicon (Si) doped gallium nitride (GaN) region by plasma-assisted molecular beam epitaxy (PA-MBE);
epitaxially depositing the short period superlattice (SPSL) region includes forming interleaved atomic monolayers of m N-polar indium gallium nitride (InGaN) layers and n N-polar gallium nitride (GaN) layers by plasma-assisted molecular beam epitaxy (PA-MBE); and
epitaxially depositing the N-polar multiple quantum well (MQW) region includes forming interleaved N-polar indium gallium nitride (InGaN) quantum wells (QW) and N-polar gallium nitride (GaN) quantum barriers (QB) by plasma-assisted molecular beam epitaxy (PA-MBE.

18. The method of manufacturing the micro light emitting device (μLED) according to claim 17, wherein the epitaxially deposited short period superlattice (SPSL) region reduces/relaxes lattice strain in the N-polar multiple quantum well (MQW) region.

19. The method of manufacturing the micro light emitting device (μLED) according to claim 17, wherein the epitaxially deposited short period superlattice (SPSL) region increases indium incorporations in the N-polar indium gallium nitride (InGaN) quantum wells (QW).

20. The method of manufacturing the micro light emitting device (μLED) according to claim 17, wherein the one or more nanowires emit red light with a peak external quantum efficiency (EQE) of 8% or greater, and a wall-plug efficiency (WPE) of 4.5% or greater for a magnesium (Mg) concentration of greater than 1020 atoms/cm⁻³ in the magnesium (Mg) doped gallium nitride (GaN) region.

21. The method of manufacturing the micro light emitting device (μLED) according to claim 14, further comprising:
epitaxially depositing a doped tunnel junction region on the N-polar multiple quantum well (MQW) region opposite the short period superlattice (SPSL) region.

22. The method of manufacturing the micro light emitting device (μLED) according to claim 21, further comprising:
filling spaces between the plurality of nanowires;
forming one or more contact regions on the tunnel junction regions of the plurality of nanowires; and
forming one or more contact regions on the substrate.

23. The method of manufacturing the micro light emitting device (μLED) according to claim 21, wherein:
epitaxially depositing the doped tunnel junction region includes forming a N-polar magnesium (Mg) doped gallium nitride (GaN) region by plasma-assisted molecular beam epitaxy (PA-MBE).
